(19) United States
(12) Patent Application Publication
(10) Pub. No.: US 2013/0125958 A1
(43) Pub. Date: May 23, 2013

(54) PREVENTING CHARGE BUILDUP IN PV MODULE BACKSHEET METAL FOIL VAPOR BARRIERS

(71) Applicant: David H. Meakin, Albuquerque, NM (US)

(72) Inventor: DAVID H. MEAKIN, Albuquerque, NM (US)

(21) Appl. No.: 13/674,509

(22) Filed: Nov. 12, 2012

Related U.S. Application Data
(60) Provisional application No. 61/561,713, filed on Nov. 18, 2011.

(51) Int. Cl. H01L 31/048; H01L 31/18

(52) U.S. Cl. CPC H01L 31/0485; H01L 31/18
USPC 136/251; 438/57

(57) ABSTRACT

Embodiments of the present invention generally relate to sealing and supporting an encapsulated photovoltaic module using a supporting frame. In one embodiment, a supporting frame is grounded and configured to support a peripheral portion of an encapsulated photovoltaic module. The peripheral portion of the encapsulated photovoltaic module may be covered and in physical contact with an electrically conductive foam tape, which is configured to protect the encapsulated photovoltaic module from being abraded by the supporting frame while providing a conductive path between a metal vapor barrier layer laminated in the encapsulated photovoltaic module and the supporting frame. The placement of the electrically conductive foam tape between the supporting frame and the encapsulated photovoltaic module insures a constant discharging of the electrostatic charges accumulated on the metal vapor barrier without any arcing.

### CROSS-REFERENCE TO RELATED APPLICATIONS

This application claims benefit of U.S. provisional patent application Ser. No. 61/561,713, filed Nov. 18, 2011, which is herein incorporated by reference.

### BACKGROUND OF THE INVENTION

1. Field of the Invention

Embodiments of the present invention generally relate to sealing and supporting an encapsulated photovoltaic module using a supporting frame.

2. Description of the Related Art

Solar cells are photovoltaic devices that convert sunlight into electrical power. Each solar cell generates a specific amount of electric power and is typically electrically connected into a circuit to produce voltages acceptable for system performance. A photovoltaic module typically encloses the solar cell circuit in a laminated package for environmental protection. For example, the laminated package may encapsulate the solar cell circuit under pressure and heat to form a laminated structure comprising glass/polymer/solar cell/polymer/backsheet. The edge of the encapsulated cell assembly may be covered by a foam tape and supported by a supporting frame for ease of handling, mechanical strength, and protection. The foam tape protects the glass of the encapsulated cell assembly from being abraded by the supporting frame. The abrasion may cause defects in the glass that will eventually cause the glass to fail.

The backsheet for used in the photovoltaic module typically consists of different layers of materials to provide functions such as environmental protection, resistance to mechanical abrasion, and electrical isolation. The backsheet may include a layer of metal vapor barrier disposed between an inner layer of, for example, polyethylene terephthalate (PET), and an outer layer of, for example, polyvinyl fluoride, to prevent moisture ingress. However, it has been observed that the metal vapor barrier may collect electrostatic charges when the photovoltaic module is placed into a PV array. These electrostatic charges can produce undesirable arcing between the metal vapor barrier and the supporting frame, causing permanent and costly damage to the photovoltaic module and possible shock hazards to persons handling the module.

Therefore, there is a need in the art for handling and supporting an encapsulated photovoltaic module without the above-mentioned issues.

### SUMMARY OF THE INVENTION

Embodiments of the present invention generally relate to sealing and supporting an encapsulated photovoltaic module using a supporting frame. In one embodiment, a method of processing an encapsulated photovoltaic module is provided. The method generally includes applying an electrically conductive tape onto a portion of the encapsulated photovoltaic module, wherein the encapsulated photovoltaic module comprises a metal vapor barrier layer in physical or electrical contact with the electrically conductive tape, and supporting the encapsulated photovoltaic module with an electrically grounded frame such that a portion of the grounded frame is in physical contact with the electrically conductive tape.

In another embodiment, a photovoltaic module is provided. The photovoltaic module generally includes an encapsulated photovoltaic module, comprising a backsheet comprising a metal vapor barrier layer, and a cover disposed over the backsheet, an electrically conductive tape configured to enclose a peripheral portion of the encapsulated photovoltaic module, and a supporting frame configured to frame the peripheral portion of the encapsulated photovoltaic module, the supporting frame being electrically grounded.

In yet another embodiment, a method of processing an encapsulated photovoltaic module is provided. The method generally includes providing an encapsulated photovoltaic module, wherein the module comprises a metal vapor barrier and wherein at least a peripheral edge of the encapsulated photovoltaic module is enclosed by an electrically conductive tape, supporting the encapsulated photovoltaic module with an electrically grounded frame such that a portion of the grounded frame is in physical contact with the electrically conductive tape to provide a constant electrical path that discharges accumulated electrostatic charges from the metal vapor barrier to the grounded frame.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a blown up view of a photovoltaic module that may be benefit from the present invention.

FIG. 2 schematically illustrates a cross-sectional view of an encapsulated photovoltaic module that may be benefit from the present invention.

FIG. 3 schematically illustrates a cross-sectional view of a supporting frame that may be used to practice various embodiments of the present invention.

### DETAILED DESCRIPTION

Embodiments of the present invention generally relate to sealing and supporting an encapsulated photovoltaic module using a supporting frame. In one embodiment, a supporting frame is grounded and configured to support a peripheral portion of an encapsulated photovoltaic module. The peripheral portion of the encapsulated photovoltaic module may be covered and in physical contact with an electrically conductive foam tape, which is configured to protect the encapsulated photovoltaic module from being abraded by the supporting frame while providing a conductive path between the supporting frame and a metal vapor barrier layer laminated in the encapsulated photovoltaic module. The placement of the electrically conductive foam tape between the supporting frame and the encapsulated photovoltaic module insures a constant discharging of the electrostatic charges accumulated on the metal vapor barrier without any arcing.

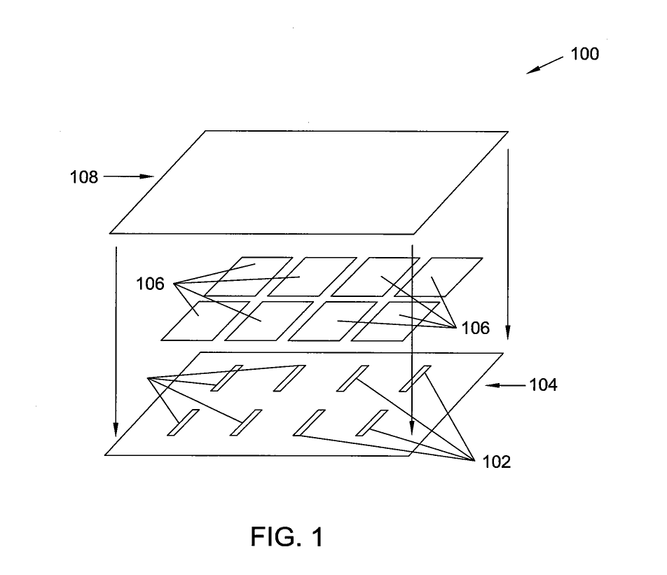

FIG. 1 depicts a blown up view of a photovoltaic module 100 that may benefit from the present invention. The photovoltaic module may be any type of photovoltaic module having solar cells that are electronically connected into a circuit and encapsulated with an upper cover and a backsheet. In one embodiment, the photovoltaic module comprises back-contact crystalline-silicon (c-Si) solar cells. The back-contact c-Si solar cells contemplated for practicing the invention are solar cells with coplanar contacts on the back surface which employ laser-drilled vias connecting the front surface carrier-collector junction to an electrode grid on the back surface. An exemplary back-contact c-Si solar cell is described in U.S. Pat. No. 5,468,652, the disclosure of which is incorporated herein by reference in its entirety.

FIG. 1 schematically illustrates electrically conductive circuit elements 102 that are pre-patterned (or placed) onto the surface of a backsheet 104. Back-contact solar cells 106 are positioned atop the electrically conductive circuit elements 102, which may be in the form of strips of electrically conductive foil. The backsheet 104 may be a multilayer structure configured to provide several functions in photovoltaic modules, such as environmental protection, resistance to cuts and mechanical abrasion, and electrical isolation. The front surface of the backsheet 104 may form from a layer of polyethylene terephthalate (PET) having a thickness within a range from about 100 microns to about 200 microns. The back surface of the backsheet 104 may form from a layer of metal vapor barrier (e.g., aluminum) having a thickness of about 15 microns to about 100 microns. The metal vapor barrier provides environmental protection to the conductive circuit elements 102 and the solar cells 106. An optional outer layer of polyvinyl fluoride (not shown) may be roll laminated onto the metal vapor barrier with an adhesive layer to further prevent moisture ingress. Other materials such as polyester, polyimides, or polyethylene may be used in place of polyvinyl fluoride to serve the same objectives.

The pattern of electrically conductive circuit elements 102 is selected based on the electrical requirements of the module to be manufactured and in part dictated by the dimensions of the solar cells to be arranged on the module. Specifically, the electrically conductive circuit elements 102 are positioned so that when they are connected by the solar cells 106, an electric circuit that is capable of generating power is created. The decisions about how precisely to configure the electrical circuit and where exactly to locate the electrically conductive circuit elements 102 relative to each other may be tailored to suit the needs of the user.

An electrically conductive material is provided between the solar cell contacts 106 and the electrically conductive circuit elements 102 on the backsheet 104 to complete the electrical circuit of the photovoltaic module. As the solar cells 106 are back-contact solar cells, both the positive polarity contacts and the negative polarity contacts of each solar cell 106 are positioned on the back surface of the solar cells 106 in electrical contact with the conductive circuit elements 102. Electrical current generated by the back-contact solar cells 106 is transported through the conductive circuit elements 102 and solar cells 106 in a series connection to a junction box or other location where the electric current can be utilized.

A sheet of polymer encapsulation (not shown) is positioned over the surfaces of the solar cells 106 and the backsheet 104. Thereafter, a cover 108 of glass is placed atop the assembled elements. It is contemplated that materials other than glass may serve the objectives and purposes of those manufacturing given modules. The module is then sealed using heat and pressure or another sealing method suited to the particular polymer encapsulation material selected, thereby forming an encapsulated photovoltaic module.

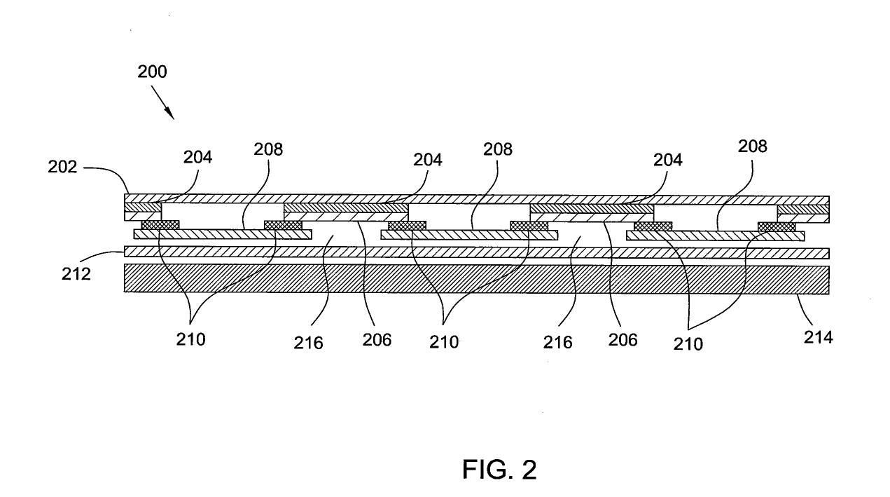

FIG. 2 schematically illustrates a cross-sectional view of an encapsulated photovoltaic module 200 that may benefit from the present invention. As discussed above, the photovoltaic module may include a backsheet 202 and a plurality of electrically conductive circuit elements 204 disposed thereon in a predetermined pattern. The backsheet 202 may be a multilayer structure as discussed above with respect to FIG. 1. To ensure adequate adhesion between the electrically conductive circuit elements 204 and the solar cells 208, a protective layer 206 may be optionally present over the electrically conductive circuit elements 204. The protective layer 206 functions to protect the electrically conductive circuit elements 204 from the environment where the electrically conductive circuit elements 204 may oxidize and lose their conductivity. It may be advantageous to choose a coating that has similar chemical characteristics to the electrical attachment material in order to avoid corrosion. In one embodiment, the protective layer 206 may include silver and may have a thickness of up to about 1000 Angstroms. In another embodiment an organic solderability preservative (OSP) may be employed. The protective layer 206 may be deposited by many deposition means such as electroless deposition or chemical bath dipping.

To electrically connect and adhere the electrical circuit elements 204 to the solar cells 208, an electrically conductive attachment layer 210 may be present. This layer is used in specific portions of the solar cell that were designed for electrical connection (“terminals”). The terminals provide regions on the solar cells 208 for electrical connection to the electrically conductive circuit elements 204. The electrically conductive attachment layer 210 may include an electrically conductive adhesive such as an epoxy with electrically conductive particles, such as silver, carbon, metal alloys with low liquidus temperatures, etc., therein. Alternatively, the electrically conductive attachment layer 210 may be a solder. The electrically conductive attachment layer 210 may be present over the entire surface of the protective layer 206 (so long as the adhesive layer does not have a negative impact upon the reflection capabilities of the protective layer 206). In one embodiment, the electrically conductive attachment layer 210 may be present in select locations between the solar cell 208 and the protective layer 206. Encapsulating material 212 and a cover 214 (e.g., glass) are sequentially present on the solar cells 208. Adjacent solar cells 208 may be spaced apart by a gap 216 such that the electrically conductive circuit elements 204, or adhesive layer 206 is present, may be exposed.

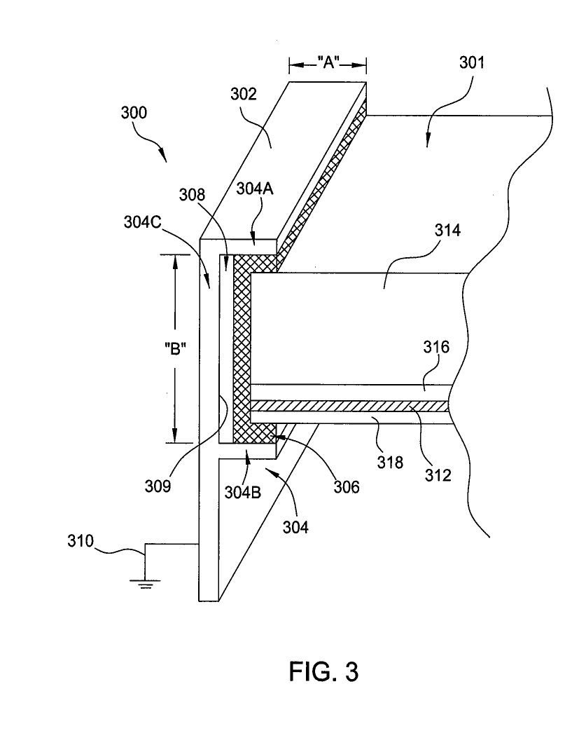

FIG. 3 schematically illustrates a cross-sectional view of a supporting frame 300 that may be used to practice various embodiments of the present invention. The supporting frame 300 generally includes a frame body 302 having an approximately U-shaped portion 304 radially extended from the frame body 302. The U-shaped portion 304 is configured to receive an encapsulated photovoltaic module 301, for example, the encapsulated photovoltaic module 100 or 200 as depicted in FIGS. 1 and 2. For clarity, the encapsulated photovoltaic module 301 only shows a cover 312 and a layer of metal vapor barrier 314 disposed between a layer of polyethylene terephthalate (PET) 316 and an outer layer of polyvinyl fluoride 318. It is contemplated that the supporting frame may be configured to support the encapsulated photovoltaic module partially or entirely around the module. While the supporting frame 300 is formed with an approximately U-shaped portion 304, the supporting frame 300 may have a variety of cross-sectional profiles such as circular or horseshoe shaped that is capable of receiving an encapsulated photovoltaic module to be framed. The previous construction is shown as an example but the invention is not limited to back contact cell modules but can be used for any module that employs a conductive metal vapor barrier in the backsheet construction

The opening of the U-shaped portion 304 may be extended inward toward the centerline of the encapsulated photovoltaic module 301 to be supported at a desired distance “A” of between about 5 mm and about 20 mm, for example, about 10 mm. The distance “B” between two opposing sides 304a, 304b of the U-shaped portion 304 may be between about 3 mm and about 10 mm, for example, about 6 mm. The distance “B” may vary depending upon the overall thickness of the encapsulated photovoltaic module 301. The U-shaped portion 304 of the supporting frame 300 is configured to house the peripheral portion of the encapsulated photovoltaic module 301 within a spacing defined by two opposing sides 304a, 304b and a section 304c (located between the two opposing sides 304a, 304b) of the U-shaped portion 304.

An electrically conductive foam tape 306, which covers or encloses the peripheral portion of the encapsulated photovoltaic module 301, may substantially fill the U-shaped portion 304 with the peripheral portion of the encapsulated photovoltaic module 301 housed within the U-shaped portion 304. The electrically conductive foam tape 306 may be formed with single sided adhesive bonded to the photovoltaic module 301 to protect the encapsulated photovoltaic module 301 from being abraded by the supporting frame 300. The electrically conductive foam tape 306 may be semiconductive foams. The electrically conductive foam tape 306 may be foams or elastomers that are coated with an electrically conductive polymer in order to provide desirable physical properties of the polymeric foams, such as compressibility, flexibility, compression set resistance. Alternatively, the electrically conductive foam tape 306 may be a polymer foam containing one or more electrically conductive fillers to serve the same objectives. The polymer for use in the electrically conductive foam tape 306 may be selected from a wide variety of thermoplastic resins, blends of thermoplastic resins, thermosetting resins, or any other suitable material that has a conductivity that is high enough to conduct electrostatic charges from the metal vapor barrier 314 formed in the backsheet. The formed electrically conductive foam tape 306 should have water vapor impermeability and sufficient flexibility to allow for expansion/contraction due to thermal cycling or processing and any difference of coefficient of temperature expansion between two different materials, for example, the encapsulated photovoltaic module 301 and the supporting frame 300.

The foam tape 306 may have a width of about 30 mm and a thickness between about 0.3 mm to about 1.5 mm, for example about 0.8 mm. The electrically conductive foam tape 306 may have adhesive properties so that it can be applied onto the peripheral portion of the encapsulated photovoltaic module 301 before inserting the module 301 within the U-shaped portion 304. Alternatively, the electrically conductive foam tape 306 may be applied onto an inner surface of the U-shaped portion 304 by any means such as manually or robotic means, followed by the insertion of the encapsulated photovoltaic module 301. Upon insertion of the encapsulated photovoltaic module 301 within the U-shaped portion 304, the conductive foam tape 306 is in physical contact with and sandwiched between the peripheral edge of the encapsulated photovoltaic module 301 and at least a portion of the supporting frame 300, such as the two opposing sides 304a, 304b and the section 304c which define the U-shaped portion 304. Particularly, the layer of metal vapor barrier 314 formed in the encapsulated photovoltaic module 301 is in physical and/or electrical contact with the electrically conductive foam tape 306. In certain embodiments, a spacing 308 may be provided between the conductive foam tape 306 and an inner surface 309 of the section 304c of the U-shaped portion 304 to leave clearance for thermal expansion. The spacing 308 may be between about 0.1 mm and about 1.2 mm, for example, about 0.6 mm.

The supporting frame 300 may be made of any material that retains its rigidity under external or internal stress and is conductive. The supporting frame 300 may be metal or a conductive composite material. In one embodiment, the supporting frame 300 is made of aluminum material. The supporting frame 300 is electrically grounded through a ground wire 310. The supporting frame 300 and the ground wire 310 provide a constant electrical path that discharges accumulated electrostatic charges from the metal vapor barrier 314 formed in the backsheet. Therefore, the electrically conductive foam tape 306 that encloses the peripheral edge of the encapsulated photovoltaic module 301 and is in physical contact with the U-shaped portion 304 of the supporting frame 300 establishes an electrical discharge path that is constant across the surfaces of the foam tape 306. The placement of the electrically conductive foam tape 306 insures a constant discharge of electrostatic charges from the metal vapor barrier 314 to the grounded supporting frame 300, thereby preventing undesirable arcing between the metal vapor barrier 314 and the supporting frame 300 that may otherwise present if the electrostatic charge was not discharged.

Benefits of the present invention include allowing the metal vapor barrier to be grounded through the electrically conductive foam tape to supporting frame without having to compromise the environmental barrier, and allowing the grounding to be accomplished without having to expose a portion of the cover (e.g., glass) and the backsheet to the raw frame metal. The placement of the electrically conductive foam tape between the supporting frame and the encapsulated photovoltaic module insures a constant discharging of electrostatic charges accumulated on the metal vapor barrier, rendering the module safe from possible shock hazards to persons handling the encapsulated module.

While the foregoing is directed to embodiments of the present invention, other and further embodiments of the invention may be devised without departing from the basic scope thereof, and the scope thereof is determined by the claims that follow.

1. A method of processing an encapsulated photovoltaic module, comprising:
applying an electrically conductive tape onto a portion of the encapsulated photovoltaic module, wherein the encapsulated photovoltaic module comprises a metal vapor barrier layer in physical and/or electrical contact with the electrically conductive tape; and
supporting the encapsulated photovoltaic module with an electrically grounded frame such that a portion of the grounded frame is in physical contact with the electrically conductive tape.

2. The method of claim 1, wherein the electrically conductive tape covers a peripheral edge of the encapsulated photovoltaic module.

3. The method of claim 2, wherein supporting the encapsulated photovoltaic module comprises framing the peripheral edge of the encapsulated photovoltaic module with an approximately U-shaped portion configured to receive the encapsulated photovoltaic module.

4. The method of claim 3, wherein the electrically conductive tape comprises a foam coated with an electrically conductive polymer.

5. The method of claim 3, wherein the electrically conductive tape comprises a polymer foam containing one or more electrically conductive fillers.

6. The method of claim 3, wherein the approximately U-shaped portion of the electrically grounded frame is configured to house the peripheral edge of the encapsulated photovoltaic module within a spacing at least defined by two opposing sides of the U-shaped portion.

7. The method of claim 1, wherein the electrically conductive tape is disposed in a manner to establish a constant electrical path between the metal vapor barrier layer and the electrically grounded frame.

8. The method of claim 1, wherein the electrically conductive tape provides sufficient flexibility to allow for expansion/contraction between the encapsulated photovoltaic module and the electrically grounded frame.

9. A photovoltaic module, comprising:
an encapsulated photovoltaic module, comprising:
a backsheet comprising a metal vapor barrier layer; and
a cover disposed over the backsheet;
an electrically conductive tape configured to enclose a peripheral portion of the encapsulated photovoltaic module; and
a supporting frame configured to frame the peripheral portion of the encapsulated photovoltaic module, the supporting frame being electrically grounded.

10. The photovoltaic module of claim 9, wherein the electrically conductive tape is in physical and electrical contact with the metal vapor barrier layer and the supporting frame.

11. The photovoltaic module of claim 9, wherein the supporting frame has an approximately U-shaped portion radially extended from the frame body.

12. The photovoltaic module of claim 11, wherein the U-shaped portion is radially extended at a distance between about 5 mm and about 20 mm.

13. The photovoltaic module of claim 9, wherein the electrically conductive tape comprises a foam coated with an electrically conductive polymer.

14. The photovoltaic module of claim 9, wherein the electrically conductive tape comprises a polymer foam containing one or more electrically conductive fillers.

15. The photovoltaic module of claim 9, wherein the electrically conductive tape has a thickness between about 0.3 mm to about 1.5 mm.

16. The photovoltaic module of claim 9, wherein the electrically conductive tape is sandwiched between the peripheral portion of the encapsulated photovoltaic module and the U-shaped portion.

17. The photovoltaic module of claim 16, further comprising a spacing provided between the electrically conductive tape and the U-shaped portion.

18. The photovoltaic module of claim 17, wherein the spacing is between about 0.1 mm and about 1.2 mm.

19. A method of processing an encapsulated photovoltaic module, comprising:
providing an encapsulated photovoltaic module, wherein the module comprises a metal vapor barrier and wherein at least a peripheral edge of the encapsulated photovoltaic module is enclosed by an electrically conductive tape;
supporting the encapsulated photovoltaic module with an electrically grounded frame such that a portion of the grounded frame is in physical contact with the electrically conductive tape to provide a constant electrical path that discharges accumulated electrostatic charges from the metal vapor barrier to the grounded frame.

20. The method of claim 19, wherein supporting the encapsulated photovoltaic module comprises framing the peripheral edge of the encapsulated photovoltaic module with an approximately U-shaped portion, and wherein an opening of the U-shaped portion is extended toward a centerline of the encapsulated photovoltaic module.
